(19) United States
(12) Patent Application Publication
(10) Pub. No.: US 2022/0140006 A1
(43) Pub. Date: May 5, 2022

(54) IMAGE-SENSOR MATRIX-ARRAY DEVICE COMPRISING THIN-FILM TRANSISTORS AND ORGANIC PHOTODIODES

(71) Applicant: ISORG, Limoges CEDEX 3 (FR)

(72) Inventors: Noémie BALLOT, GRENOBLE CEDEX 09 (FR); David BLANCHON, GRENOBLE CEDEX 09 (FR); Richun FEI, GRENOBLE CEDEX 09 (FR)

(21) Appl. No.: 17/433,468

(22) PCT Filed: Feb. 18, 2020
(86) PCT No.: PCT/EP2020/054211

§ 371 Date: Aug. 24, 2021

(30) Foreign Application Priority Data
Feb. 25, 2019 (FR) FR1901899

(51) Int. Cl. H01L 27/30; H01L 51/44

(52) U.S. Cl. CPC H01L 27/307; H01L 51/442

(57) ABSTRACT

An electro-optical device for a matrix image sensor, has thin-film transistors and organic detectors, which integrates a line driver circuit, with thin-film transistors in a peripheral area. A light screen is provided on a topological level supported by a dielectric layer above the thin-film transistors, which are individual screens, for each pixel in a matrix area, and a general screen for all the transistors of the driver circuit. The general screen in the peripheral area is further used as an interconnection structure to bias an upper electrode of the organic photodiodes of an active area to a bias voltage, by an overlapping in direct contact. In the active area, a topological level of the upper electrode is separated from the topological level of a pixel electrode by an active organic structure. In the peripheral area, these two topological levels are present and formed directly on each other, with no interposition.

### FIELD

The present invention concerns an optoelectronic device, comprising a detection matrix based on thin-film transistors and organic photodiodes, called OPDs, to form a matrix image sensor (or pixelated imager).

### BACKGROUND

The invention particularly, but not exclusively, applies to image sensors used for access control (services, goods, airports, etc.). Taking the field of sensors of prints (of a finger or of the palm of a hand), an image of the papillary pattern corresponding to the alternation of valleys and of ridges present on the epidermis at the skin surface is to be captured. The image capture process is the following: the object having its image desired to be captured (a finger for example) is placed or presented in a detection window of the sensor. An image capture is triggered (automatically, by detection or on demand, for example, with a trigger button). This causes the illumination of the object, by an illumination source integrated to the sensor (for example, a white light source (leds) integrated on one side, associated with an optical focusing system, or a sheet of light-emitting diodes placed between the detection surface and the object). And the sensor measures in each pixel the quantity of light reflected by the object towards it during a determined integration period. This quantity is higher or lower according to whether it is reflected by a ridge or groove area of the epidermis. This integration phase is followed by a pixel readout phase, which aims are converting the quantities of charges integrated by each of the pixels into digital values corresponding to a grey scale. A digitized image of the object, ready to be used/processed by algorithms specific to the concerned application, is obtained. For a print, the obtained print data will be compared with reference data.

Image sensors based on organic photodiodes associated with thin-film transistors TFT are good candidates to cover the wide panel of possible applications, and are booming. These sensors are indeed inexpensive, reliable, and fast, but also thin, light, and robust, which allows their easy integration on any type of support, transparent or not, rigid as well as flexible, in any type of application environment, such as for example on the wheel of a vehicle, a bank card, a cell phone, a computer, a check point (airport).

In these sensors, the detection matrix comprises a vertical stack of a matrix array of organic photodiodes ensuring the light detection function (conversion of photons into electric charges) on a matrix array of thin-film transistors, ensuring the electronic control function enabling to drive and read the pixels. It is spoken of an active or passive matrix according to whether it uses a plurality of transistors or a single one, per pixel. In the following, the term active matrix is simply used, it being understood that this covers both possibilities.

Active matrices based on thin film transistors, or more simply TFT transistors, have widely developed for the control of display pixels (LCD, OLED) and the associated technologies have improved with the increasing demand for always larger and higher-performance displays. Different TFT transistor technologies are thus available, which have been developed to decrease their costs, to improve their electric performance (power consumption, switching speed, stability), their bulk (miniaturization), to allow the use of support substrates much less expensive than silicon and that may be rigid as well as flexible, etc. These technologies particularly differ by the channel semiconductor material: amorphous silicon (a-SI:H), indium gallium zinc oxide (IGZO), organic (OTFT), or also low-temperature polysilicon (LTPS). Different topologies are also provided: planar, with a staggered structure, or with an inverse staggered structure.

Image sensors have benefited from these technological developments and integrate such active matrices with TFT transistors for the detection pixel control in image sensors. It is then needed to manage the image capture and to allow the reading from the pixels.

When the matrix comprises a single transistor per pixel (passive matrix), it simply enables to select one pixel to transmit the charges collected by the pixel during the period of exposure to light, to an electronic readout circuit. When the matrix comprises other transistors in addition to this selection transistor (active matrix), it allows a more advanced electronic control of the pixels and particularly enables to reset the pixels, prevent their saturation, apply improved readout techniques in order to improve the signal-to-noise ratio. In particular, a follower-assembled transistor is provided, which ensures a charge-to-voltage conversion within the pixel, and the selection transistor then transmits to the readout electronics a signal level representative of the collected charges. For applications such as print capture, a matrix with one transistor per pixel, more compact and less expensive, will generally be sufficient and the following description will be placed in this context. However, all that will be said hereafter applies to a matrix which would comprise more than one transistor per pixel.

In the invention, the topological aspects of an image sensor formed by stacking of an organic light detection matrix array on such a TFT transistor matrix array are considered, to improve its compactness and its electric performance, including its resistance to electrostatic discharges, contributing to its reliability and its optical qualities. Before explaining the topological aspects of this stack enabling to explain the issue in question, the electric diagram of a matrix image sensor should be briefly reminded.

FIG. 1 shows the main structural elements of an image sensor: an active detection matrix array 10, a circuit 20 for driving the array rows, and a circuit 30 for reading from the cells of the array.

Matrix array 10 is formed of pixels, all identical, arranged in rows and columns. The pixel P_{i,j} located on the row of rank i and the column of rank j of the array comprises a selection transistor Ts having its gate coupled to a row conductor Lᵢ coupling the gates of the selection transistors of all the pixels of the row of rank i; and having a terminal drain or source electrode, for example, source s, coupled to a column conductor Cⱼ coupling the sources of the selection transistors of all the pixels of the column of rank j. The other terminal electrode, drain d, is coupled to pixel electrode E1, which in the illustrated example corresponds to the cathode of photodiode OP. The other photodiode electrode E2, the anode in the example, is based to a bias voltage Vbias, which is the same for all the pixels in the array: this is why, in the drawing, all the electrodes E2 are coupled in common by conductors to a power supply bus which receives bias voltage Vbias.

In practice, this electrode E2 is formed on the last level of the stack of the photodiode layers, in a continuous layer structure (and/or of a mesh) covering the surface of the matrix, and it is biased to the bias voltage, generally by an interconnection to a peripheral bus running along at least one side of the matrix. The bias voltage is applied on this bus by contacting pads provided on the edge of the panel, allowing a connection by a flexible ribbon to an external power source.

It should be noted that the light detection surface of the pixel is inscribed within the hatched rectangle in the drawing, delimited by the two column conductors Cⱼ and Cⱼ₊₁ and the two row conductors Lⱼ and Lⱼ₊₁.

Driver circuit 20 allows the sequential selection (it is also spoken of a scanning) of each pixel row, one after the other, in each capture period. As well known, the selection of a row of detection pixels of the matrix array corresponds to the application to the corresponding row conductor of a gate control voltage pulse, which enables to switch to the on state, for the time of the pulse, the transistors Ts of the pixels of the selected row. Readout circuit 30 can then read these pixels, each via the associated column conductor: in each selected pixel, the electrons originating from the photons received by the pixel and collected by the cathode are transferred via the selection transistor which is on, onto the associated column conductor. This column conductor is coupled to a corresponding input of readout circuit 30, which conventionally comprises an amplifier stage 30a followed by an analog-to-digital converter 30b. The digital data at the converter output are transmitted to an image processing system (not shown). When the pixel comprises a plurality of transistors, the selection transistor is no longer coupled directly to the pixel electrode, but indirectly by a transistor which performs a current-to-voltage conversion. However, the readout addressing principle remains similar.

Drive circuit 20 is based on a shift register structure, with as many output stages as matrix array rows which allow the selection and the reading of the pixels, row by row. As well known and described in technical literature, a corresponding electric diagram comprises arrangements of transistors and of capacitive elements, particularly so-called bootstrap capacitive elements, and these electronic elements are driven at high frequency to allow the propagation of a high voltage pulse from one output stage to another. These arrangements are designed to enable to drive at high frequency output lines (the row conductors), which are highly capacitive.

These driver circuits or line drivers have long been manufactured in CMOS technology. They were thus external peripheral circuits, coupled by flexible ribbons to contacting pads of the detection matrix panel. Along with technical progress, high-performance designs of line drivers based on TFT transistors (and capacitive elements) have been provided. These integrated line drivers are generally designated in literature with the term “Gate on Array” (or its acronym GOA). The interconnection with the row conductors (and the associated reliability aspects) is more optimal (compactness, cost, reliability). In particular, the number of contacting points on the component panel to be provided for the external connections/interfaces is significantly decreased. Manufacturing costs are also decreased since the TFT transistors forming driver circuit 20 (GOA) and active array 10 are then collectively formed within the same technological step on the same substrate. The output of each output stage of the shift register is formed in alignment with and connected to a corresponding row conductor of the matrix array. This integration is in keeping with the market demand for an increasing compactness and reliability, at a lesser cost.

The invention concerns such an optronic component integrating on the same component panel the detection matrix and the circuit for driving the lines of the detection matrix and an object of the invention is an optimized design of such a component, for a greater reliability and compactness, with no degradation of the manufacturing cost, taking into account the different connector, electric or light disturbance issues present.

In particular, it is well known that light alters/modifies the electric properties of the semiconductor channel material of TFT transistors. More precisely, the exposure to light causes a drift in the threshold voltage resulting in non-uniformities of the behavior of the switching transistors of the matrix, some becoming less conductive, or even no longer conductive at all, due to a threshold voltage that becomes too high. This results in degrading the output image quality, and thus the reliability of the sensor: the error rate associated with the concerned application will increase (print not recognized). This also alters the lifetime of the sensors. This issue concerns all the TFT transistors integrated on the component panel, that is, the transistors of the active matrix as well as those of the driver circuit.

Electronic techniques (dynamic solutions) for compensating for these threshold voltage variations by increasing the level of the control voltages are known, but this is very expensive (dynamic solutions).

Another, passive, solution is to provide for the transistor channels to be protected from light by a screen. The gate of the TFT transistors which, conventionally, is made of an opaque material (silver, molybdenum, copper, . . . ) may in certain cases fulfill this screening function when light arrives through the gate (before arriving onto the channel). This solution is dependent on the topology of the transistors (staggered or inverse staggered) and on the illumination mode and on the position of the object to be imaged, through the front side and/or the back side of the sensor. It is also dependent on the manufacturing techniques and on the TFT transistor technology: in certain cases, the gate may not sufficiently protect the channel at the level of the edges, whereby the protection will not always be optimal. This more particularly concerns the case where the gate is formed last, after the channel and the source/drain electrodes (staggered structure).

It is thus generally necessary to integrate a specific element in the stack of layers of the component to fulfill this screening function, while ascertaining not to or to insignificantly disturb the transmission of useful light and/or of illumination towards the active detection structure. In other words, the aperture ratio of the pixel should not or as little as possible be decreased.

The specifications of the image sensor for which the optronic component is intended thus have to be taken into account to determine how to integrate these screens. Indeed, there may be different conditions from one sensor to the other: the useful light to be detected generally arrives under a normal incidence through the upper transparent electrodes of the organic photodiodes, through the front side of the sensor. However, it may arrive through the back support substrate side (necessarily transparent in this case), or even both through the front side or the back side in sensors offering both possibilities. For the illumination source of the object to be imaged: in certain sensors, it is integrated, for example, in a housing, on the front side or on the back side. In other sensors, the illumination source is integrated in the very topology of the component (on a topological level of the stack), on the back side or on the front side (sheet of OLED organic diodes used for lighting).

The very technology of the TFT transistors must also be taken into account, and in particular whether they are staggered or inverse staggered.

As previously indicated, this issue of protection of the TFT transistor channels from light concerns the transistors of the detection matrix as well as those of the driver circuit. For the latter, this problem may however be solved with the integration into the target sensor, when an encapsulation plate made of an opaque material with a transparent detection window corresponding to the useful (active) area to be exposed to light is provided.

This however only takes into account the light sources in the operational conditions of use of the sensor. Now, while it has been indicated that the liquid and low thermal budget method of manufacturing the organic photodiodes is compatible with TFT transistor technologies, there has however been observed that during the manufacturing of the organic matrix on top of the topological TFT stack, radiations, particularly the UV rays used, were not without influence on the electric characteristics of the TFTs. In other words, by measuring the electric characteristics of the TFT transistors formed on a panel, before and after the forming of the organic matrix, variations can be observed. This may affect the TFT transistors of the active matrix as well as those of the driver circuit.

An object of the invention is to provide a component stacking an organic photodetection matrix on top of a matrix array of TFT transistors which, by design, efficiently protects all the TFT transistors located in the same topological panel level, from the radiations used during the organic matrix stacking process and from the radiations present in operation, whatever the technology or the type of these transistors and the detection and illumination specificities of the concerned image sensor. The disparities between the electric characteristics of the transistors of the component are thus efficiently reduced, contributing to improving the sensor performance (reliability, lifetime).

In the invention, this is desired to be done without degrading the compactness of the component, and preferably while improving it, to satisfy the market demand for ever smaller and thinner sensors, allowing their easy integration, and for handling-resistant sensors. The component size is conditioned by the number and the thickness of the stack layers; but also by the surface of the peripheral area to be provided around the matrix (for a given imager size) to form or connect the electric and electronic elements necessary to drive the pixel matrix.

It has already been explained hereabove that it is advantageous to integrate line driver circuit 20 in this peripheral area. However, in this peripheral area, the contacting points allowing the connections to the electronic readout circuit, which is generally external (CMOS circuit), also has to be placed, as well as a metal conductive bus to ensure the basing of upper electrode E2. This electrode biasing should be able to guarantee the highest surface current uniformity so that the photoelectric conversion in the pixels and the reading is as homogeneous as possible across the entire matrix surface, ensuring a good image quality. Also, generally, it is provided for the bus to run along both sides of the matrix, from a panel edge having contacting points for the connection (typically by a flexible ribbon) provided thereon to an external bias source; and the electrode plate extends from the matrix over these two sides to achieve the connection to this bus, by overlapping (direct contact) or by vertical interconnects (vias).

### SUMMARY

An object of the invention is to address these various reliability, performance, and compactness issues, with a solution which is easy to implement and of low cost, independent from the TFT technologies used and from the functional specificities of the sensors.

A matrix optoelectronic device for an image sensor according to the invention comprises on a same insulating support substrate a matrix array of pixels aligned in rows and columns, formed in an active detection area and a driver circuit comprising transistors for the control of the pixel rows, formed in a peripheral area, each pixel comprising at least one transistor which has a pixel selection transistor function, and an organic photodiode between a lower electrode specific to the pixel and connected to said at least one pixel transistor, and an upper electrode common to the pixels, and the optoelectronic device being formed by a stack of successive assemblies of layers on the dielectric support substrate, which comprises:
in the active matrix area:
   a first assembly of thin films of transistors forming said at least one transistor of the pixels, covered with an insulating passivation layer continuously extending over said first assembly, and
   a second assembly of layers forming the organic photodiodes of the pixels and comprising a first conductive layer stack level which is a patterned level, supported by said passivation layer, forming the lower electrode in each pixel, a second stack level of a layer or layers of active organic structure, and a third conductive layer stack level forming the upper electrode of the pixels extending above the active structure, and in each pixel, said first conductive layer stack level also forming in each pixel a light screen covering at least the pixel transistor surface, and
in the peripheral area:
   said first layer assembly which forms said transistors of the driver circuit,
   the first patterned conductive layer stack level supported by said passivation layer, which forms a light screen which extends continuously above said transistors of the driver circuit, and comprises a contacting area allowing a connection to an external bias voltage,
   the upper electrode of the pixels extends in the peripheral area to cover in direct electric contact said light screen, forming an interconnect for the biasing of the upper electrode to voltage Vbias.

According to a first aspect, the first patterned layer stack level comprises at least one conductive layer made of an opaque metal which is patterned to form the light screen patterns in the active area and in the peripheral area.

Advantageously, the first stack level comprises at least one second layer made of a transparent conductive material which forms the upper surface of said first stack level.

According to another aspect, the first stack level forms bilayer patterns at the surface of the passivation layer, comprising an opaque pattern formed in the surface plane of the passivation layer, and a transparent pattern which covers and extends beyond each side of said opaque pattern on the passivation layer.

In a variant, the first stack level forms three-layer patterns at the surface of the passivation layer, which comprise an opaque pattern fully encapsulated in the thickness of a transparent pattern.

### BRIEF DESCRIPTION OF THE DRAWINGS

Other features, details, and advantages of the invention will appear from the reading of the following description, in connection with the accompanying drawings, provided as an example, and which respectively show:

FIG. 1: a general block diagram of an active optical detection matrix circuit and of the peripheral addressing and readout circuits, according to the state of the art, in an example of a pixel structure comprising a TFT transistor and a photodiode used in reverse structure.

FIG. 2: a simplified diagram in top view of an optoelectronic device according to the invention.

FIG. 3: a top view, corresponding to an embodiment of the invention.

FIG. 4: a simplified cross-section view of the topological stacks (levels/layers) of a device according to the invention in an embodiment more particularly adapted to a front side illumination and light detection, in an example of monolayer pixel electrode structure made of an opaque material.

FIG. 5: a variant of FIG. 4, using a multilayer pixel electrode structure in a “generally” opaque version.

FIG. 6: a variant of FIG. 5, illustrating a “generally transparent” version.

### DETAILED DESCRIPTION

For clarity, in the drawings, the same elements are designated with the same references. Also, only those elements useful to the understanding of the invention have been detailed. It is also useful to specify that in the present description, the terms “connected”, “interconnected”, “connection”, or “interconnection” designate a direct connection between two conductive elements, with no interposed electronic component; and the terms “linked” or “coupled” designate an electrical link that may be direct or via an electronic component such as, for example, a transistor. Further, the drawings have been made to ease the understanding of the invention. Particularly, the different elements of the drawings are not to scale and only those elements useful to the understanding of the invention have been shown.

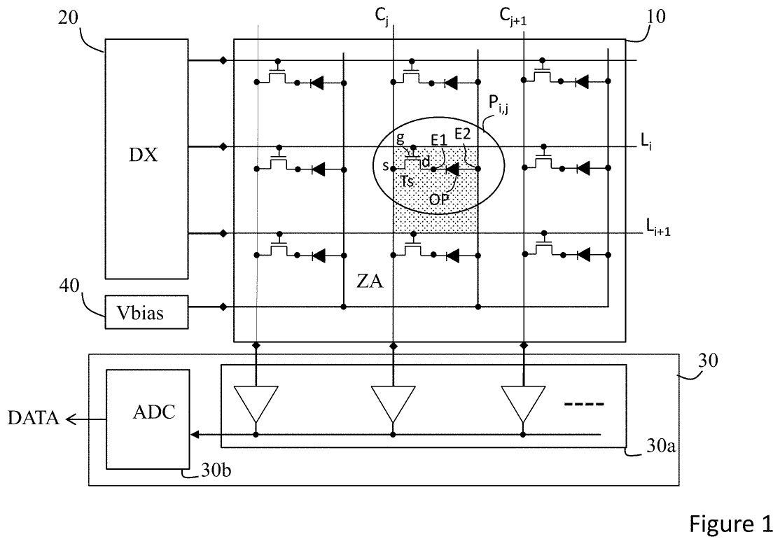

It has been seen that FIG. 1 shows a matrix 10 of detection pixels and the peripheral driver, readout, and bias circuits 20, 30, and 40. The pixels are each formed of an organic photodiode OP and of at least one TFT transistor, noted TS, which enables to select the pixel by a respective output of driver circuit 20. The organic photodiode has a lower electrode E1 which forms the pixel electrode and an upper electrode E2 which, in practice, is an electrode common to all pixels. In the example, the organic photodiode is used in reverse structure: E1 corresponds to the cathode (electron injection) and E2 to the anode (hole injection), which is then biased to a negative or zero voltage Vbias.

The invention is explained for such a use of a photodiode in reverse structure, but applies as well to a forward-used structure (in this case, E2 would correspond to the cathode and voltage Vbias would be a positive voltage).

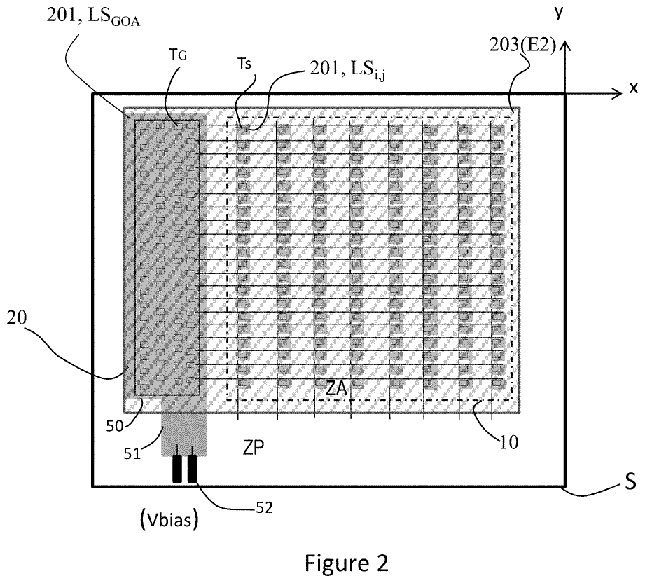

In an optoelectronic device according to the invention and as shown in FIG. 2, detection matrix 10 and driver circuit 20 are formed on a same component panel. The matrix is formed in a so-called active area ZA (delimited in dotted lines) at the upper surface of a support substrate S. The term “active” refers as well to the active matrix of TFT transistors (whether there is one or more than one transistor per pixel) as to the function of electric charge photogeneration in the active organic structure of the pixels. Driver circuit 20 is formed in peripheral area ZP, outside of the active area, on a side of the active matrix in line with the row conductors that it has to drive. The TFT transistors are represented by small rectangles in the drawing. In the active area, they are represented by one rectangle per pixel, regularly aligned along the matrix array columns and rows, corresponding to the example of described pixel structure, with a single selection transistor Ts. For driver circuit 20, a regular arrangement of assemblies of rectangles representing transistors Tg of the different shift register stages has been shown. This drawing is an indication only of the structure of the pixels and of the driver circuit, to help the understanding of the invention.

The forming of the device is obtained in usual fashion, by a stacking of successive layers. Certain layers of the stack are patterned by using masks to form elements insulated from one another in the active area and/or the peripheral area, which is particularly true for the layers forming the TFT transistors (Ts, T_{GOA}) and pixel electrodes E1.

The active organic structure between the two electrodes is present in the active area only and may be formed in continuous form (unpatterned) in this area, as illustrated. It may however also be formed in individual active elements (patterned). It comprises, mixed or next to one another, donor and acceptor semiconductor polymers, forming the PN junction, and a layer for improving the charge injection, at least between the junction and the electrode which is used as a cathode (E1 in the example). These aspects are well known by those skilled in the art and will not be detailed, since the invention does not concern the actual organic structure.

In the following, the term “topological level” is used to designate the layer(s) which correspond to a functional element of the device and which may thus comprise or correspond to one or a plurality of layers. Each mono- or multilayer topological level may be associated with a qualifier or a plurality of qualifiers indicating an electric (such as “conductive”, “dielectric”, etc.) or optical (for example “transparent”, “opaque”) property; or designating a functional electronic assembly, such as: “TFT” to designate all the layers forming the TFT transistors, “organic” or “active organic” to designate the layer(s) forming the organic PN junctions as well as the possible intermediate layers of interface with the lower (pixel) and upper (common) electrodes.

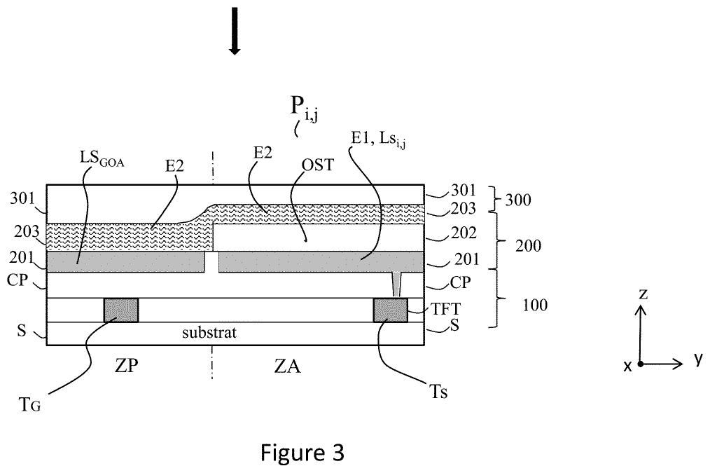

FIG. 3 is a general cross-section view of the electro-optical device of FIG. 2, showing the main topological levels. One can successively find in the active area, and in this order, from the upper surface of a substrate S:
a first stack level 100 which corresponds to the TFT transistors. This level then forms the transistors Tg of driver circuit 20 and the pixel transistors, Ts in the example. These transistors are represented by a block with no details of their structure, and are covered with an insulating (dielectric) passivation layer CP which forms the upper surface of stack 100. It may be a quite thick resin layer, which forms a level surface for the rest of the stack.
a topological level 200 corresponding to the detection matrix and which breaks down into a first conductive topological level 201 for the forming of the lower electrodes E1 of the pixels, on passivation layer CP; a second active organic level 202 which corresponds to the active organic structure OST including the organic PN junction layer(s) and the intermediate charge injection layers associated with junction electrodes E1 and E2; and a third conductive topological level 203 of upper electrode E2; and then
an upper topological level 300 mainly comprising a passivation layer 301, to obtain a planar surface at the upper surface of the stack, and which also has the function of protecting the organic materials of active structure OST from the oxygen of air and from humidity.

The stack might comprise other topological levels, not shown. Particularly, on level 300, one or a plurality of additional topological levels may for example be formed to form a sheet of light-emitting diodes for illumination; or also an optical filtering function to select a wavelength range. Also, the active organic structure is here disclosed as a continuous structure in the active area, where the individual detection elements are defined in each pixel by pixel electrode E1. It may however be formed in a patterned structure with as many patterns as pixels. In this case, there generally are additional topological levels corresponding to stop layers (to form the patterns) or charge blocking layers. These different aspects are known by those skilled in the art. All the aspects of the forming of an organic detection matrix for an image sensor are well known and need not be detailed any further, since the invention concerns an advantageous use of the lower and upper electrode topological levels to improve the reliability of the device and its compactness.

The conductive topological level 201 is that corresponding to pixel electrode E1, which ensure an electronic function of collection of the electric charges (electrons, in the case of a cathode) generated by the photoelectric conversion of photons received in the PN junction formed by active structure OST between pixel electrode E1 (bottom) and upper electrode E2 (top). This pixel electrode E1 is interconnected on the drain of the selection TFT transistor Ts of pixel P_{i,j} by vertical interconnection (via an opening made in the thickness of dielectric layer(s) between the surface of the passivation layer and the drain).

This conductive topological level 201 of pixel electrode E1 is used in the invention to form in the active layer individual optical screens for the TFT transistor(s) in each pixel, and in the peripheral area, a common optical screen for the transistors of the driver circuit. These screens enable to protect the TFT transistors from the radiations arriving through the upper layers/levels: all along the rest of the steps of forming of the upper topological levels, comprising the organic, upper electrode, and final passivation topological levels; and then, in operation, in the image sensor (useful light, illumination light).

Referring to FIG. 2: an individual screen LS_{i,j} is thus formed in each pixel in the active area ZA, which covers (at least) the TFT transistor(s) of the pixel; and a general screen LS_{GOA} is formed in the peripheral area ZP, which covers all the TFT transistors of the driver circuit. This screen LS_{GOA} is further used as an interconnection structure to bias the upper electrode E2 of the organic photodiodes of the active area to bias voltage Vbias, by an overlapping in direct contact. In practice, upper electrode E2 covers the surface of detection matrix 10 and extends in the peripheral area, on the side of driver circuit 20, on the upper surface of plate 50 of screen LS_{GOA}; and screen LS_{GOA} comprises on a side of plate 50 a finger-shaped region 51 extending towards an edge of the substrate to allow the application of external bias voltage Vbias via contacting pads 52.

More precisely, and as clearly visible in the cross-section view of FIG. 3, in active area ZA, the two conductive topological levels 201 (pixel electrode E1) and 203 (upper electrode E2) are separated by the topological level of organic active structure 202 (PN junction and/or intermediate layers of interface with the electrodes); in the peripheral area, these two topological levels 201 and 203 are present but directly formed on each other, in direct contact, with no other interposed levels/layers.

This configuration according to the invention has multiple advantages. First, it enables to insert the light screening function enabling to protect all the TFT transistors of the component in the peripheral area as well as in the active area, on a topological level already existing in the device. This is optimal in terms of compactness and of manufacturing cost. This screening function is efficient to protect the TFT transistors from the light arriving through the upper topological levels, during the manufacturing method as well as in operational mode, and this, totally independently from the TFT technology used. Further, since the screen protecting the transistors of the driver circuit is not left floating, but is taken to a fixed voltage (voltage Vbias), it is avoided for electric (capacitive) couplings with the electronics of the driver circuit to occur. This also enables to protect the driver circuit from possible electrostatic discharges.

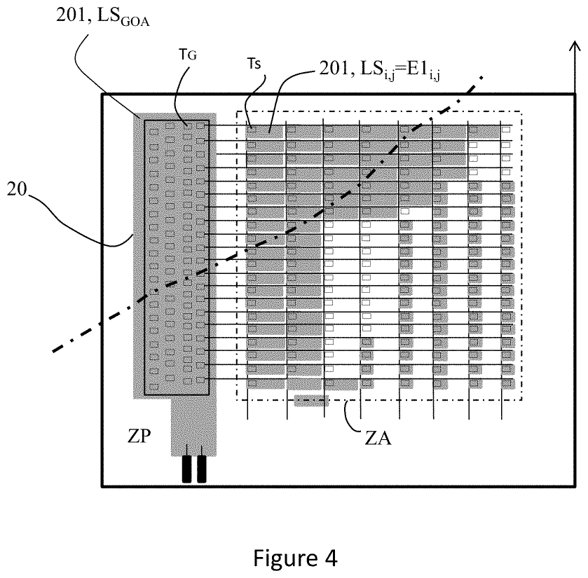

If the device is intended for a sensor where the illumination and the light to be detected arrive from the front side, the upper electrode has to be transparent but pixel electrode E1 may be opaque (FIGS. 3 and 4). In this case, pixel screen LS_{i,j} may be confounded with pixel electrode E1. This is what in shown in FIG. 3: the pixel electrode is made of a monolayer opaque metal structure on level 201 and the same opaque conductive pattern carries out the electronic function of collection of the pixel electrode charges and the function of optical individual screening for the TFT transistor(s) of the pixel.

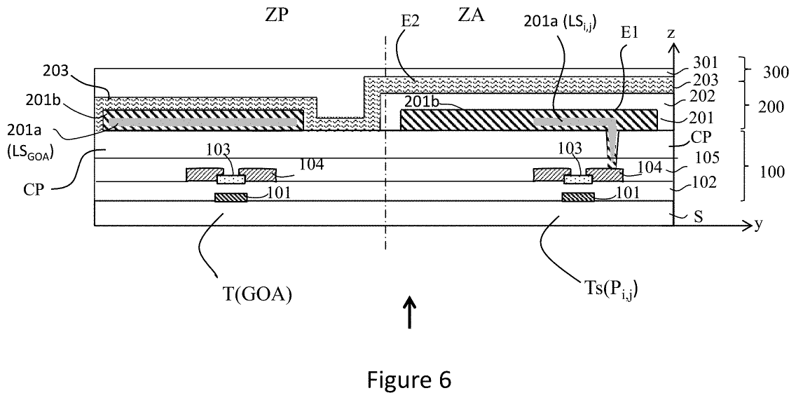

However, if the device is intended for a sensor where the illumination and/or the light to be detected arrive from the back side, pixel electrode E1 has to be generally transparent, that is, transparent everywhere except for a small opaque surface above the transistor(s), which forms pixel screen LS_{i,j}. This is the case shown in FIGS. 2 and 6. This is done by advantageously providing a topological pixel electrode structure which is an at least opaque/transparent bilayer, enabling to integrate and locate an opaque pattern in the pixel electrode pattern. Advantageously, this at least bilayer structure enables to form an opaque or “generally opaque” pixel electrode pattern (it will be seen hereafter that the electrode may be transparent on the edges); or a “generally transparent” pixel electrode pattern, that is, transparent except above the TFT transistor(s) of the pixel, by adjusting the opaque mask pattern to the specificities of the target product.

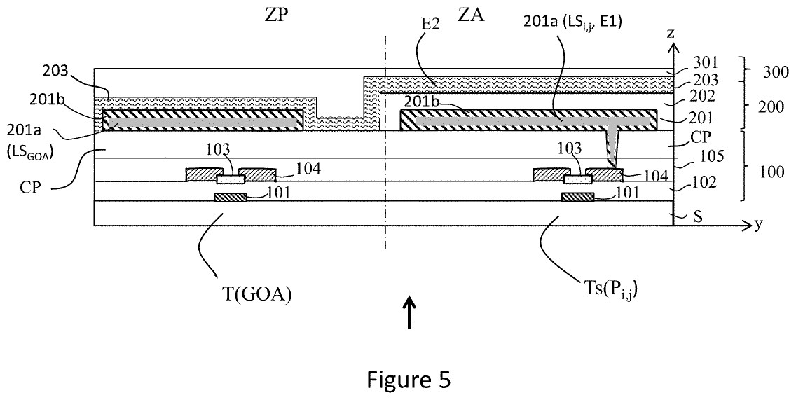

More precisely, a conductive topological level 201 which is a multilayer comprising at least one transparent conductive layer 201b on an opaque metal layer 201a is advantageously provided in the invention. The upper transparent layer level 201b is patterned to form the pixel electrode pattern E1 in each pixel; and the lower opaque layer level 201a is used to form the individual pixel screen LS_{i,j}. That is, the transparent level is always present, over the entire pixel electrode surface, and the opaque level pattern size is adjusted according to the specificities of the product, by changing the associated mask pattern. Thus:
the surface of the screen LS_{i,j} of FIG. 2 or 6, is circumscribed to the “TFT” surface of the pixel and the pixel electrode is “generally transparent” (the surface area occupied by the TFT transistor(s) is small as compared with the pixel electrode surface area). A corresponding cross-section view is shown in FIG. 5;
the surface LS_{i,j} of the screen of FIG. 3, 4, or 5 substantially corresponds to the pixel electrode surface. The pixel electrode is then generally opaque. The term “generally opaque” means that the pixel electrode may be totally opaque as in FIG. 3 (monolayer structure made of opaque metal, or perfectly aligned opaque metal/transparent metal structure); or not be opaque on the edges, for example, because the transparent upper level slightly protrudes (as a cover) on each side of the opaque pattern, or completely encapsulates it as illustrated in FIG. 5, as will be explained hereafter.

In both configurations, exactly the same sequence of technological steps for manufacturing the device is applied; the mask pattern of opaque layer 201a, in the active area, is adapted to form a pixel electrode which will be generally transparent or generally opaque, according to the specificities of the target product.

This structure is also advantageous in terms of costs and of selection of the materials to form this conductive topological level 201. Indeed, for the upper conductive level 201b, transparent conductive oxides such as ITO or ZnO, which are current, low-cost, and stainless conductive materials and which, in known fashion, have electronic properties (electronic affinity, work function) compatible with the organic active structures formed above may be used to form layer 201b. The collection of the photogenerated charges in the active structure, on the lower electrode (pixel electrode) E1, is thus favored. For the lower opaque layer level 201a, it is possible to use metals currently used to form conductive levels of TFT transistors, for example, but non-exhaustively: silver, molybdenum, copper.

In practice, conductive level 201 may for example be formed on the upper surface of passivation layer CP, by using two successive deposition steps: a deposition and a patterning of a layer of opaque material 201a (forming of the screen patterns), followed by a deposition and a patterning of a layer of transparent material 201b.

Preferably, the pattern of transparent layer 201b extends beyond the pattern of opaque layer 201a, like a cover, so that from one product to another, only the opaque layer mask pattern has to be adapted (to the size of the TFT surface of the pixel; to the generally opaque or transparent nature of the pixel electrode). This further extension of the transparent material 201b also enables to improve the mechanical bonding to the passivation layer, and to protect the opaque metal from oxidation, which would result in altering its electric conduction properties.

Advantageously, the opaque pattern is integrated across the thickness of transparent material, which improves all these effects (bonding, lack of oxidation). A transparent/opaque/transparent three-layer pattern is obtained, as shown in FIGS. 5 and 6. For this purpose, a first level of a transparent material layer 201b is deposited; above this first transparent level, opaque metal 201a is deposited and patterned; then, a second level of transparent material layer 201b is deposited, after which the obtained multilayer structure is patterned to form the pixel electrode pattern in the active area, and the screen in the peripheral area.

FIGS. 5 and 6 further show, as an indication, the elements forming the gate, channel, drain, and source of the TFT transistors and of the corresponding topological levels: conductor 101 (gate), gate insulator 102, semiconductor 103 (channel), conductor 104 (drain/source), and final dielectric 105 (typically, a nitride: SiN, SiNx, SiOx, SiON, etc.), for an example of inverse staggered structure, which is more favorable in terms of compactness and of electric mobility. The passivation layer CP added on top is generally made of an organic dielectric material, typically a resin, for example, SU8.

It should be noted that it may also be provided for passivation layer CP to comprise, in addition to a resin layer, a surface layer made of an inorganic dielectric material, preferably the same material as that of layer 105, to favor the mechanical bonding of opaque metal 201a. These different variants are encompassed by the invention.

The invention which has just been explained applies to all TFT transistor technologies, staggered as well as inverse staggered. Particular, in staggered structures, it is known that the gates (opaque metal) may not perfectly protect the channel edges from light arriving through the upper levels. The screens formed according to the invention on the pixel electrode level then enable to reliably obtain the optical protection. For light arriving from the bottom, the substrate should in this case be made opaque at the transistor level (“black matrix”).

Concerning the upper electrode conductive topological level 203, it may be made of materials capable of being deposited by liquid and low thermal budget techniques and adapted to forming this electrode: metal such as Al, Ag, Au, and Pt in an ultrathin film for transparency; transparent conductive oxides such as ITO (indium tin oxide), IZO (indium zinc oxide); an organic conductor, such as PEDOT-PSS (mixture of two polymers: poly(3,4-ethylenedioxythiophene) (PEDOT) and sodium poly(styrene sulfonate) (PSS).

In particular, it is generally advantageous in terms of cost and of quality of transparency (when it is necessary) to use a material based on PEDOT-PSS. Metal, inserted in the form of wires (silver wires for example), or in the form of a grid, may be associated therewith to lower its surface resistance. In this case, with a layer 201b made of transparent conductive oxide such as ITO or ZnO, there is a good electronic compatibility (work function) with the upper electrode.

As an example, in a practical embodiment of the invention, a transparent/opaque/transparent three-layer pattern is formed on the level 201 of the stack with, as an opaque material 201a, molybdenum deposited with a 200-nanometer thickness, encapsulated in ITO (201a) with an ITO thickness of 20 nanometers under the opaque material and of 30 nanometers above.

1. A matrix optoelectronic device for an image sensor, comprising on a same insulating support substrate a matrix array of pixels aligned in rows and columns, formed in an active detection area and a driver circuit comprising transistors for the control of the pixel rows, formed in a peripheral area, each pixel comprising at least one transistor which has a pixel selection transistor function, and an organic photodiode between a lower electrode specific to the pixel and connected to said at least one pixel transistor, and an upper electrode common to the pixels, and the optoelectronic device being formed by a stack of successive assemblies of layers on the dielectric support substrate, which comprises:
in the active matrix area:
a first assembly of thin films of transistors forming said at least one transistor of the pixels, covered with an insulating passivation layer continuously extending over said first assembly, and
a second assembly of layers forming the organic photodiodes of the pixels and comprising a first conductive layer stack level which is a patterned level, supported by said passivation layer, forming the lower electrode in each pixel, a second stack level of a layer or layers of an active organic structure, and a third conductive layer stack level forming the upper electrode of the pixels extending above the active structure, and in each pixel, said first conductive layer stack level also forming in each pixel a light screen covering at least the pixel transistor surface, and
in the peripheral area:
said first assembly of layers which forms said transistors of the driver circuit,
the first patterned conductive layer stack level supported by said passivation layer, which forms a light screen extending continuously above said transistors of the driver circuit, and comprises a contacting area allowing a connection to an external bias voltage,
the upper electrode of the pixels extends in the peripheral area to cover in direct electric contact said light screen, forming an interconnect for the biasing of the upper electrode to the voltage.

2. Matrix optoelectronic device according to claim 1, wherein said first patterned layer stack level comprises at least one conductive layer made of an opaque metal which is patterned to form an individual light screen in each pixel in the active area and a light screen pattern for the driver circuit in the peripheral area.

3. Matrix optoelectronic device according to claim 2, wherein said first conductive layer stack level comprises at least one second layer made of a transparent conductive material which forms the upper surface of said first stack level.

4. Matrix optoelectronic device according to claim 3, wherein said first stack level forms bilayer patterns at the surface of the passivation layer, comprising an opaque pattern formed in the surface plane of the passivation layer, and a transparent pattern which covers and extends beyond each side of said opaque pattern on the passivation layer.

5. Matrix optoelectronic device according to claim 3, wherein said first stack level forms three-layer patterns at the surface of the passivation layer, which comprise an opaque pattern fully encapsulated in the thickness of a transparent pattern.

6. The matrix optoelectronic device according to claim 1, wherein in each pixel, the light screen surface corresponds to the electrode surface of the pixel.

7. The matrix optoelectronic device according to claim 1, wherein in each pixel, the light screen surface is circumscribed to the pixel transistor surface.

8. The matrix optoelectronic device according to claim 3, wherein said transparent conductive material is a conductive oxide.

9. The matrix optoelectronic device according to claim 1, wherein said third stack level forming the upper electrode is based on PEDOT-PSS.

10. The matrix optoelectronic device according to claim 1, wherein the thin-film transistors are formed in a thin-film technology from the following group: amorphous silicon, with indium gallium zinc oxide, organic, with low-temperature polysilicon.

11. An image sensor integrating a matrix optoelectronic device according to claim 1.
